(19) United States
(12) Patent Application Publication
(10) Pub. No.: US 2008/0204979 A1
(43) Pub. Date: Aug. 28, 2008

(54) Enclosure Assembly

(75) Inventor: Nicolaas Antonie Van Rijswijk, Oss (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/911,125

(22) PCT Filed: Apr. 4, 2006
(86) PCT No.: PCT/IB06/51017

§ 371 Date: Oct. 10, 2007

(30) Foreign Application Priority Data
Apr. 13, 2005 (EP) 05102913.0

(51) Int. Cl. H05K 5/00

(52) U.S. Cl. 361/679

(57) ABSTRACT

The invention provides a hingeably closeable enclosure assembly, wherein at least two enclosure parts (10, 20) are connected by a hinge element (30), which is accommodated in a recess (13, 23). The hinge element (30) is flexible, and preferably ribbon-shaped, and is slideably moveable in the recess. This configuration allows the hinge to be invisible from the outset, and to occupy the least amount of space.

The present invention relates to an enclosure assembly, in particular for enclosing electronics, according to the preamble of claim 1.

Such enclosure assembly provides an enclosed space, in which electronics or the like may be enclosed. The enclosure has an outer wall, which is substantially free from projections, and especially from outside hinges.

A known enclosure assembly with hinges that are not visible from the outside is for example a car, or piece of furniture, having doors. For design, safety reasons etc., the door hinges are often present on the inside. For example U.S. Pat. No. 6,487,755 discloses a hidden hinge for furniture doors.

A problem of the known assembly is that the hinge occupies a relatively large amount of space. This is caused by the hinge projecting into the enclosed space. Although the hinge may be covered or hidden in a wall, thus does not reduce the amount of space occupied by the hinge. Especially in the case of enclosures for electronics etc., where miniaturization is required, such hinges limit the amount of available space inside the enclosure, given predetermined outside dimensions of the enclosure.

It is hence an object of the present invention to provide an enclosure assembly of the kind mentioned above, in which the hinge occupies a reduced amount of space.

This object is achieved by the enclosure assembly according to claim 1, which is characterized in that the first recess extends substantially parallel with the first wall, and the hinge element is flexible and is slideably movable within the first recess. The flexible hinge element allows a hinging movement of the enclosure part with respect to each other, while the hinge element is fully accommodatable in the recess, by sliding into it, when the enclosure assembly is in the closed position. Herein, the expression “substantially parallel” comprises the situation in which said recess is not completely straight, but e.g. undulates or is curved, and wherein the general direction of the recess makes an angle of maximum 15 degrees with the first outer surface. This ensures that the least amount of space is occupies, especially in the case of the recess being completely parallel to the first outer surface.

Advantageous embodiments have been set forth in the dependent claims, some of which will be further elucidated below.

In a special embodiment, the hinge element is substantially ribbon-shaped, having a flat surface extending substantially parallel to the first outer surface. Such hinge element has a favorable combination of flexibility in one direction, the hinge direction, and strength in the other directions, while the dimensions in the direction into the enclosed space may be kept to a minimum. Of course, other shapes are also possible, such as a round or fiber-shape, although the latter shapes have a somewhat reduced stability when sliding or pushing the hinge element into the recess.

The recess is advantageously, but not necessarily, adapted to the (cross-sectional) shape of the hinge element. For example, in the case of a ribbon-shaped hinge element, it is advantageous to provide a slit-like recess, since in that case the least amount of space is occupied by the combination recess with hinge element. It also helps in better guiding the hinge element when sliding it within the recess.

It is to be understood that a flexible hinge element relates to a hinge element made of an intrinsically flexible material, not a series of coupled but intrinsically rigid elements such as a chain.

The first and second element lock means are not particularly limited, as long as at least one thereof allows a sliding movement of the hinge element in the recess. For example, the hinge element may comprise an elongated slit therein, through which a bar or the like projects. It is also possible to fixedly attach one end of the hinge element to one of the enclosure parts, only the other end being slideably moveable in the recess. This fixed attachment may be brought about by means of gluing, welding etc.

In a particular embodiment, the first element lock means comprises a first snap lock means at a first end thereof, the first recess comprising a first element lock portion co-operating with the first snap lock means and having a smaller diameter than the first snap lock means. Snap lock means, which are per se known in the art, are a convenient means of securably locking two parts together. The snap lock action is brought about by pushing a resilient, e.g. hook-like part of the hinge element past the element lock portion, e.g. a constricted part of the recess. The snapped back snap lock means now reliably prevent escape of the hinge element from the recess. Yet some movement is allowed, by inserting the hinge element even more deeply into the recess.

It is noted that the expression “at an end” relates to the lock means being positioned at an extreme end of the hinge element, but also near such end. Any part of the hinge element positioned more towards the extreme end thereof than the lock means are irrelevant for the purpose of the present invention, but may yet be present.

In a special embodiment, the second element lock means are provided at a second end opposite the first end, wherein the second enclosure part comprises a second recess with a second element lock portion co-operating with the second element lock means. This embodiment, with recesses in both enclosure parts, allows accommodating both ends thereof in a recess, which provides more protection for the lock means and lock portions against damage when the enclosure assembly is in use.

In a particular embodiment, the first and second enclosure part each comprise an additional first and second screw hole, respectively, adjacent the first and second recess, and which are aligned in a closed position of the enclosure assembly. The provision of such screw holes, at least one of which is provided with a thread, allows the use of a screw to fixedly join the two enclosure parts to each other. This is advantageous for protecting the enclosed inner space and its contents against undesired access from outside, or also against ingress of dust, water etc. Especially in the case of electronics, such enclosure assembly may easily be made waterproof, which needless to say is a great advantage for use, especially outdoors.

In a special embodiment of the enclosure assembly according to the invention, the second element lock portion comprises a through hole through the second wall. With an appropriate size of the through hole, it is easy to insert the hinge element from outside, through said hole, into the recess. In this way the two enclosure parts may easily be connected with the hinge element. It is of course also possible to insert the hinge element from the other side of the through hole.

It is now also possible to lock the hinge element in a different way. In particular, the second element lock means comprises a projection having a diameter that is larger than a minimum diameter of the through hole. This is a very simple yet effective way of securely locking the hinge element to the corresponding enclosure part. Since the hinge element is also coupled to the other enclosure part, an expedient coupling is brought about with the least number of means, yet allowing freedom of movement. Said projection may be a portion of the hinge element truly having a larger diameter, or it may be an outwardly bent part.

In a special embodiment, the second element lock means comprises an opening which is positioned across the second screw hole. Inserting a screw into the hole, and through the opening, automatically securely connects the hinge element to the corresponding (second) enclosure part. Since many embodiments will actually already provide for such a screw, a very reliable locking means and portion may be provided in this way, by simply bending the appropriate end portion of the hinge element towards the screw hole, such that the opening in the hinge element overlaps the screw hole. Note that in this case it is not necessary for the hinge element to have a part with a diameter larger than the through hole, although this is still possible and offers of course the same additional advantage.

It is advantageous for an enclosure assembly according to the invention, wherein a screw is provided in the screw holes, to use a screw with a threadless part between threaded parts. In this way the screw may reliably be attached to the screw hole, without the risk of loss thereof. This has an additional advantage that, when the enclosure is reopened, the screw or screws need not be held or stored separately. Other means of securely coupling the screw or screws to the enclosure assembly are not excluded.

A special enclosure assembly according to any preceding claim comprises a plurality of hinge elements. In many cases these multiple hinge elements will be provided in separate recesses, for example one near every screw (or a number thereof) along one side of the enclosure assembly. This allows the assembly to be opened easily, with one of the two parts being swung aside with respect to the other part, said part, and preferably all of the screws used, being securely coupled to the other remaining part.

It is remarked here that the enclosure assembly according to the present invention is not limited to the embodiments described above. For example, the enclosure assembly is not limited to two enclosure parts, but may rather also comprise three or more parts, much the same way as for example a closet may comprise a main part and two or more hinged doors.

The invention is now further elucidated with respect to exemplary embodiments, with reference to the drawings in which:

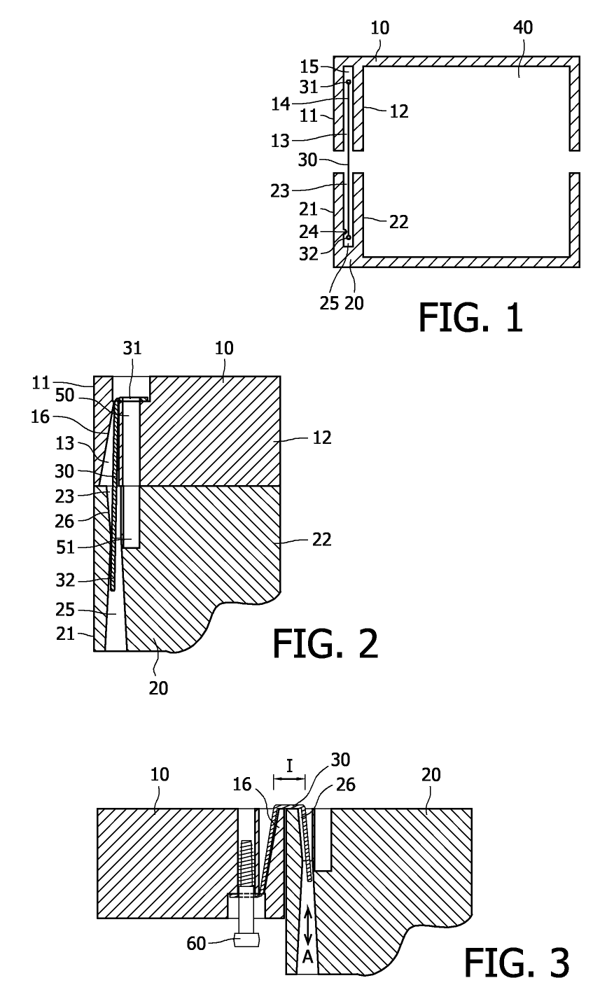

FIG. 1 diagrammatically shows a cross-sectional view of an enclosure assembly according to the invention;

FIG. 2 shows a diagrammatic cross-sectional view of a detail of a second embodiment of the enclosure assembly according to the present invention; and

FIG. 3 diagrammatically shows the embodiment of FIG. 2 in an open and bent over position.

FIG. 1 diagrammatically shows a cross-sectional view of an enclosure assembly according to the invention.

Herein 10 denotes a first enclosure part with a first outer surface 11 and a first inner surface 12, and a first recess 13 with first element securing means 14.

20 denotes a second enclosure part with a second outer surface 21 and a second inner surface 22, and with a second recess 23 with second element securing means 24.

A hinge element 30 comprises first snap lock means 31 and second snap lock means 32. Reference numerals 15 and 25 denote a first and second sliding space.

Inner space 40 is enclosed by the enclosure assembly in closed position.

As shown in FIG. 1, the enclosure assembly is substantially symmetrical, although this need not be the case in an actual embodiment. Furthermore, the walls of the enclosure parts in which the recesses are present have not been drawn to scale. In fact, the thickness thereof has been exaggerated.

Hinge element 30 has been inserted into the first recess 13 and is secured to the first enclosure element 10 by means of pushing the first snap lock means 31, for example a resilient hook or the like, past the first element securing means 14. The first element securing means 14 may be any type of projection into the recess 13 that co-operates with the first snap lock means 31, such that the diameter of the first snap lock means 31 is larger than the diameter of the first recess 13 at the position of the first element securing means 14, as is known in the art per se.

In an analogous version, the hinge element 30 is secured to the second enclosure part 20 by means of co-operating second element securing means 24 and second snap lock means 32.

It is remarked here that the “first” and “second” enclosure parts need not be the same parts as those referred to in the claims as the first and second enclosure parts. It is rather a way of discerning two parts present in the embodiments, while from the context it will always be clear which part is meant.

The first and second enclosure part 10, 20 are shown in a spaced apart position. When bringing the first and second enclosure parts 10, 20 together, in order to close the enclosure, the hinge element 30 slides more deeply into the first and second recesses 13, 23. Thereto, sliding spaces 15 and 25 are present beyond the position of the first and second securing means 14, 24. Note that it is also possible to fixedly attach the hinge element 30 to one of the first or second enclosure parts 10, 20. In that case, it is not even necessary to provide a recess in the enclosure part to which the hinge element 30 has been fixedly attached. In such case, simply gluing, riveting, etc. would also suffice. Of course, the sliding space in the other enclosure part should then of course be increased to allow for a similar play between the first and second enclosure parts 10, 20.

Since the hinge element 30 is flexible, moving the first and second enclosure parts 10 and 20 apart, also allows the latter to be pivoted with respect to each other by bending the hinge element 30. This will be further elucidated in FIG. 3.

The first recess 13 and the second recess 23 are preferably aligned with their respective openings, such that the first outer surface 11 and the second outer surface 21 are substantially level, or at least fit closely or in any other desired fashion. In this way, a smooth total outer surface of the enclosure assembly is provided, with a hinge that is totally invisible, both from the outside and from the inside, since the first inner surface 12 and the second inner surface 22 may likewise be made to fit closely to one another. Furthermore, it is clear that the least possible amount of space is taken up by this hinge.

The hinge element 30 may be made of any desired flexible material, but is preferably made of a material with an appropriate rigidity, such as many plastics and metals or alloys. Said rigidity, in combination with the thickness of the material, should be sufficient to allow the hinge element 30 to be pushed easily into the recess 13, 23, beyond the element securing means 14, 24 and further into the sliding space 15, 25. Of course, still sufficient flexibility for bending the hinge element 30 should be ensured.

The shape of the hinge element 30 is not particularly limited, and may for example be wire-like, having a circular, oval etc. cross section. In particular, however, the hinge element 30 is substantially ribbon-shaped. This offers high flexibility in one direction, i.e. around a line parallel to the flat surface of said ribbon, and perpendicular to the long axis, while providing rigidity in other directions. Furthermore, the total strength of the hinge element is increased, without increasing the thickness thereof and thus the required thickness of the wall of the enclosure parts. Such a ribbon-shaped hinge element is also useful for guiding the first and second enclosure parts 10, 20 with respect to each other when opening the enclosure assembly. In other words, especially a ribbon-shaped hinge element functions fully as a conventional hinge for a door, etc.

FIG. 2 shows a diagrammatic cross-sectional view of a detail of a second embodiment of the enclosure assembly according to the present invention. Herein, as throughout the drawings, similar parts are denoted by like reference numerals.

The first and second enclosure parts 10, 20 are shown in a closed or abutting position. Inner and outer surfaces 11, 21 and 12, 22, respectively again fit closely together, although this is not necessary.

The hinge element 30 comprises a screw hole 31 at a bent over end thereof. At an opposite end, snap lock means 32 are indicated while element securing means in the second recess 25 have not been indicated, since they extend in a plane projecting out of the plane of the drawing.

Furthermore, 50 and 51 denote first and second screw recesses, of which at least the second screw recess 51 is threaded in order to allow the first and second enclosure parts 10, 20 to be fixed with respect to each other by means of inserting a screw (not shown). By inserting a screw, or any other desired fixing means, through the screw hole 31 and into the screw recesses 50, 51, it is possible to fixedly secure the hinge element 30 to the first enclosure part 10. This allows the enclosure assembly to be reliably closed and still allows re-opening thereof. The second enclosure part 20 is still secured, though slidably, through the hinge element 30 by means of the co-operating element securing means and snap lock means. The sliding space 25 allows the first and second enclosure parts 10, 20 to be separated from each other when the screw is loosened or removed.

First recess wall surface 16 and second recess wall surface 26 are beveled, which allows more easy bending over of the hinge element 30. This will be elucidated in FIG. 3.

Note that the recesses 13, 23 are shown to be present between the screw recess 50, 51 and the outer surfaces 11, 21. Alternatively, they may be provided on any other side of the screw recesses 50, 51. Although the configuration shown is preferable for bending over the hinge element 30.

FIG. 3 diagrammatically shows the embodiment of FIG. 2 in an open and bent over position.

Screw 60 has been loosened, and first and second enclosure parts 10 and 20 have been riveted about hinge element 30, thus fully opening the enclosure assembly.

Length 1 indicates the thickness of the parts of the enclosure parts 10 and 20 between the first recess wall surface 16 and the first outer surface 11, and between the second recess wall surface 26 and the second outer surface 21, plus twice the thickness of the hinge element 30. In order to be able to position the enclosure parts 10, 20 in the position as shown, the hinge element 30 should have a sufficient length. “Sufficient” means that the distance over which the hinge element 30 may slide in a closed position of the enclosure parts 10, 20 in the direction indicated by arrows A is at least equal to the length 1. In other words, snap lock means 32, or any other desired element lock means, should be provided at a distance into the relevant recess of at least length 1 beyond the respective element securing means. Of course, if it is not required for the first and second enclosure parts to be fully opened with respect to each other, but for example only over 90° or any other desired angle, the required (additional) length of the hinge element 30 may be made less.

The beveled recess wall surfaces 16 and 26 are preferable, not only because this reduces the required extra length, and thus the depth of the recesses for the hinge element, but also reduces the risk of damaging the hinge element when bending over the first and second enclosure parts 10, 20 with respect to each other.

While the invention has been shown by means of exemplary embodiments and a description thereof, the scope of the invention is not to be construed as being limited thereto. The true scope of the invention is defined by the appended claims.

1. Enclosure assembly, which is hingeably closeable to substantially enclose an inner space (40), and which comprises
a first enclosure part (10), with a first wall having a first outer surface (11);
a second enclosure part (20), with a second wall having a second outer surface (21); and
a hinge with a hinge element (30) comprising first and second element lock means (31, 32) and securely coupling the first and the second enclosure part (10, 20),
wherein at least the first wall has a first recess (13) therein for accommodating the hinge element (30),
characterized in that
the first recess (13) extends substantially parallel with the first outer surface (11), and the hinge element (30) is flexible and is slideably movable within the first recess (13).

2. Enclosure assembly according to claim 1, wherein the hinge element (30) is substantially ribbon-shaped, having a flat surface extending substantially parallel to the first outer surface (11).

3. Enclosure assembly according to claim 1, wherein the first element lock means comprises a first snap lock means (31) at a first end thereof, the first recess (13) comprising a first element lock portion (14) co-operating with the first snap lock means (31) and having a smaller diameter than the first snap lock means (31).

4. Enclosure assembly according to claim 1, wherein the second element lock means are provided at a second end opposite the first end, wherein the second enclosure part (20) comprises a second recess (23) with a second element lock portion (24) co-operating with the second element lock means (32).

5. Enclosure assembly according to claim 4, wherein the first and second enclosure part (10, 20) each comprise an additional first and second screw hole (50, 51), respectively, adjacent the first and second recess (13, 23), and which are aligned in a closed position of the enclosure assembly.

6. Enclosure assembly according to claim 5, wherein
the second element lock portion comprises a through hole through the second wall.

7. Enclosure assembly according to claim 6, wherein the second element lock means comprises a projection (24) having a diameter that is larger than a minimum diameter of the through hole.

8. Enclosure assembly according to 5, wherein the second element lock means comprises an opening (31), which is positioned across the second screw hole (50).

9. Enclosure assembly according to claim 5, wherein a screw (60) is provided in the screw holes (50, 51).

10. Enclosure assembly according to claim 1, comprising multiple hinge elements (30).
